(19) United States
(12) Patent Application Publication
(10) Pub. No.: US 2024/0282750 A1
(43) Pub. Date: Aug. 22, 2024

(54) SEMICONDUCTOR PACKAGE

(71) Applicant: SAMSUNG ELECTRONICS CO., LTD., Suwon-si (KR)

(72) Inventors: SEOKBEOM YONG, Suwon-si (KR); Kyungsuk Oh, Suwon-si (KR)

(21) Appl. No.: 18/413,184

(22) Filed: Jan. 16, 2024

(30) Foreign Application Priority Data
Feb. 21, 2023 (KR) 10-2023-0023159

(51) Int. Cl. H01L 25/065; H01L 23/00; H01L 23/48

(52) U.S. Cl. CPC H01L 25/0657; H01L 23/481; H01L 24/08; H01L 24/16; H01L 2224/08145; H01L 2224/16145; H01L 2224/16227; H01L 2225/06568

(57) ABSTRACT

A semiconductor package including a package substrate; an upper chip on the package substrate; a passive element chip between the upper chip and the package substrate; and a lower chip between the passive element chip and the package substrate, wherein the passive element chip includes a through electrode connected to the lower chip; and a plurality of passive elements on the through electrode, and the upper surface of the passive element chip is in contact with the lower surface of the upper chip.

### CROSS-REFERENCE TO RELATED APPLICATION

This application is based on and claims priority under 35 U.S.C. § 119 to Korean Patent Application No. 10-2023-0023159, filed on Feb. 21, 2023, in the Korean Intellectual Property Office, the disclosure of which is incorporated by reference herein in its entirety.

### BACKGROUND

### 1. Field

Embodiments relate to a semiconductor package.

### 2. Description of the Related Art

As the electronic industry develops rapidly and in order to meet the needs of users, electronic devices are becoming more compact and lightweight. As electronic devices are miniaturized and more lightweight, semiconductor packages used therein may also be miniaturized and more lightweight, and should exhibit high reliability along with high performance and large capacity. As the semiconductor package has high performance and high capacity, power consumption of the semiconductor package may be increasing.

### SUMMARY

The embodiments may be realized by providing a semiconductor package including a package substrate; an upper chip on the package substrate; a passive element chip between the upper chip and the package substrate; and a lower chip between the passive element chip and the package substrate, wherein the passive element chip includes a through electrode connected to the lower chip; and a plurality of passive elements on the through electrode, and an upper surface of the passive element chip is in contact with a lower surface of the upper chip.

The embodiments may be realized by providing a semiconductor package including a package substrate; a first chip connection terminal on the package substrate; a lower chip on the package substrate and connected to the package substrate through the first chip connection terminal; a second chip connection terminal on the lower chip, the second chip connection terminal being smaller than the first chip connection terminal; a passive element chip on the lower chip and connected to the lower chip through the second chip connection terminal; and an upper chip on the passive element chip, wherein the passive element chip includes a first substrate including a through electrode therein connected to the second chip connection terminal; and a second substrate on the first substrate, providing a first surface in contact with the first substrate and a second surface opposite to the first surface, and connected to the through electrode, the upper chip includes a third surface in contact with the second surface of the second substrate, a fourth surface opposite to the third surface, and a logic element therein, and the second substrate includes a passive element therein.

The embodiments may be realized by providing a semiconductor package including a package substrate; a first chip connection terminal on the package substrate; a lower chip on the package substrate and connected to the package substrate through the first chip connection terminal; a conductive post on the package substrate, the conductive post being adjacent to the lower chip; a second chip connection terminal on the lower chip, the second chip connection terminal being smaller than the first chip connection terminal; a passive element chip on the lower chip, the passive element chip including a through electrode connected to the second chip connection terminal and a plurality of passive elements on the through electrode; an upper chip in contact with a top surface of the passive element chip, the upper chip including a logic element; a sealing layer sealing the lower chip, the passive element chip, and the upper chip and having an upper surface on the same plane as an upper surface of the conductive post; and an upper redistribution structure on the conductive posts and the sealing layer and electrically connected to the conductive posts.

### BRIEF DESCRIPTION OF THE DRAWINGS

Features will be apparent to those of skill in the art by describing in detail exemplary embodiments with reference to the attached drawings in which:

FIG. 1 is a cross-sectional view of a semiconductor package according to an embodiment;

FIG. 2 is an enlarged view of a portion P in FIG. 1;

FIG. 3 is an enlarged cross-sectional view of the passive element shown in FIG. 2;

FIG. 4 is a cross-sectional view of a semiconductor package according to another embodiment;

FIG. 5 is a graph illustrating effects of a semiconductor package according to an embodiment; and

FIGS. 6 to 12 are cross-sectional views of stages in a process of manufacturing the semiconductor package of FIG. 0.1

### DETAILED DESCRIPTION

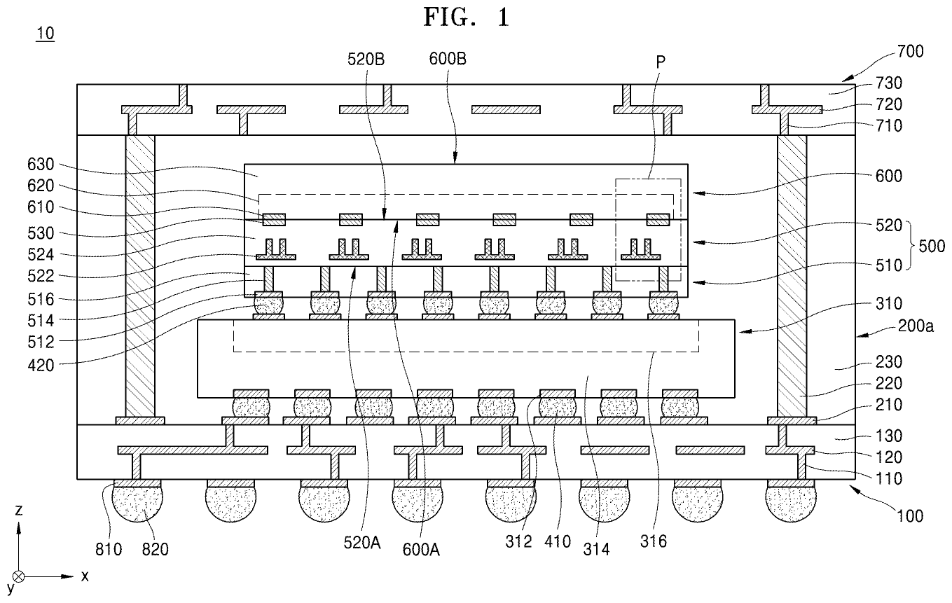

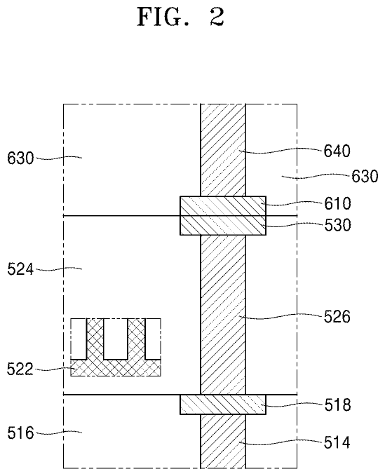

FIG. 1 is a cross-sectional view of a semiconductor package 10 according to an embodiment. FIG. 2 is an enlarged view of a portion P in FIG. 1.

The semiconductor package 10 according to an embodiment may be a 3D integrated circuit (IC) package in which a plurality of semiconductor chips are sequentially stacked.

Referring to FIGS. 1 and 2, the semiconductor package 10 according to an embodiment may include a package substrate 100, a lower chip 310, a passive element chip 500, an upper chip 600, a plurality of first and second chip connection terminals 410 and 420, a vertical connection structure 200a, a molding (e.g., sealing) layer 230, and an upper redistribution structure 700.

Here, two directions parallel to the upper surface of the package substrate 100 and perpendicular to each other are defined as a first horizontal direction (X direction) and a second horizontal direction (Y direction), and a direction perpendicular to the upper surface of the package substrate 100 is defined as a vertical direction (Z direction). Unless otherwise noted, the above definition of direction is the same for all of the drawings.

The package substrate 100 may be, e.g., a printed circuit board (PCB). The package substrate 100 may include a substrate base 130 including an epoxy resin or polyimide. In an implementation, the package substrate 100 may include conductive patterns 120 buried in the substrate base 130 and conductive vias 110 connected to the conductive patterns 120 through a portion of the substrate base 130. The substrate base 130 may include an insulating material. As the insulating material, a thermosetting resin, such as epoxy resin, a thermoplastic resin, such as polyimide, or an insulating material in which these resins are impregnated into core materials, such as inorganic fillers or glass fibers (glass fiber, glass cloth, glass fabric), e.g., prepreg, Ajinomoto build-up film (ABF), FR-4, bismaleimide triazine (BT), or the like, may be used.

The conductive patterns 120 may extend (e.g., lengthwise) in a first horizontal direction (X direction) or a second horizontal direction (Y direction) within the package substrate 100, and the conductive vias 110 may extend in a vertical direction (Z direction) within the package substrate 100. In an implementation, as illustrated in the drawings, each of the conductive vias 110 may have a uniform diameter along the vertical direction (Z direction), or the conductive vias 110 may be tapered toward the lower surface of the package substrate 100. In this case, the semiconductor package 10 may be provided by a chip last process of forming the plurality of semiconductor chips 310, 500, and 600 after forming the package substrate 100. In an implementation, the conductive vias 110 may be tapered toward the upper surface of the package substrate 100. In this case, the semiconductor package 10 may be provided by a chip first process of forming the package substrate 100 after providing the plurality of semiconductor chips 310, 500, and 600.

In an implementation, external connection pads 810 may be on the lower surface of the substrate base 130. External connection terminals 820 may be attached to the external connection pads 810. The external connection terminals 820 may be, e.g., solder balls. The external connection terminals 820 may provide an electrical connection between the semiconductor package 10 and an external device.

The conductive vias 110, the conductive patterns 120, and the external connection pads 810 may include a conductive material, which may include, e.g., copper (Cu), gold (Au), silver (Ag), nickel (Ni), tungsten (W), aluminum (Al), or combinations thereof. In an implementation, the conductive vias 110 and the conductive patterns 120 may further include a barrier material to help prevent the conductive material from diffusing out of the conductive vias 110 and the conductive patterns 120. The barrier material may include, e.g., titanium (Ti), tantalum (Ta), titanium nitride (TiN), tantalum nitride (TaN), or a combination thereof.

In an implementation, the lower chip 310 may be mounted on the package substrate 100. The lower chip 310 may include lower and upper surfaces opposite to each other, and lower chip pads 312 may be on the lower surface of the lower chip 310. The lower chip 310 may include a lower logic device 316 inside the lower chip body 314. The lower chip pads 312 of the lower chip 310 may be electrically connected to the lower logic device 316 through a wiring structure inside the lower chip body 314.

In an implementation, the lower chip 310 may be a non-memory chip. Accordingly, the lower logic device 316 may be a non-memory device. In an implementation, the lower chip 310 may be a logic chip including a deep learning model, a microprocessor, a graphic processor, a signal processor, a network processor, a chipset, an audio codec, a video codec, or an application processor.

In an implementation, the lower chip 310 may include a volatile memory chip or a non-volatile memory chip. In an implementation, the lower logic device 316 may be a volatile memory device or a non-volatile memory device. The volatile memory chip may include, e.g., dynamic random access memory (DRAM), static RAM (SRAM), thyristor RAM (TRAM), zero capacitor RAM (ZRAM), or twin transistor RAM (TTRAM). In an implementation, the non-volatile memory chips may include, e.g., flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, or insulator resistance change memory.

The lower chip 310 may be mounted on the package substrate 100 in a face-down method or a flip chip method. In an implementation, a lower surface of the lower chip 310 on which the lower chip pads 312 are formed may face the package substrate 100. The lower chip pads 312 of the lower chip 310 may be electrically connected to the package substrate 100 through the first chip connection terminals 410. The lower chip pads 312 may be terminals for transmitting input/output data signals of the lower chip 310 or terminals for power or grounding of the lower chip 310.

In an implementation, the passive element chip 500 may be mounted on the lower chip 310. The passive element chip 500 may be smaller than the lower chip 310. In an implementation, a widest surface (e.g., maximum width of a surface) of the lower chip 310 may be wider than a widest surface of the passive element chip 500. The widest surface referred to herein may mean a maximum width of a surface parallel to the horizontal directions (X and Y directions).

The passive element chip 500 may include a first substrate 510 including a through electrode therein. The first substrate 510 may be a substrate closest or proximate to the lower chip 310 among a plurality of substrates or chips that may be mounted on the lower chip 310. Passive element chip pads 512 may be on the lower surface of the first substrate 510. In an implementation, lower surfaces of the passive element chip pads 512 may be on the same plane as the lower surface of the passive element chip 500. The semiconductor package 10 may include a second chip connection terminal 420 on the lower surface of the first substrate 510, and the second chip connection terminal 420 may be attached to a lower surface of the passive element chip pad 512. The second chip connection terminal 420 may provide an electrical path by connecting a through electrode 514 to be described below to lower chip 310 below the passive element chip 500.

The first substrate 510 of the passive element chip 500 may include a through electrode 514 connected to the first substrate body 516 and the lower chip 310. The through electrode 514 may extend through the first substrate body 516 in the vertical direction (Z direction). In an implementation, the first substrate body 516 may include Si, and the through electrode 514 may correspond to a through silicon via (TSV). In an implementation, the through electrode 514 may be a via-first structure formed before the formation of the integrated circuit layer, a via-middle structure formed after the formation of the integrated circuit layer and before formation of the wiring layer, or a via-last structure formed after the formation of the wiring layer. In an implementation, as illustrated in FIG. 1, the through electrode 514 may correspond to the via-middle structure. In an implementation, the through electrode 514 in the semiconductor package 10 of this embodiment may be formed in the via-first or via-last structure. The through electrode 514 may provide an electrical path connecting a passive element 522 in the second substrate 520 (to be described below) and the lower chip 310.

In an implementation, the first substrate body 516 may include Si, or the first substrate body 516 may be composed of various types of materials according to embodiments. In an implementation, the first substrate body 516 may include a semiconductor material, such as a group IV semiconductor material, a group III-V semiconductor material, a group II-VI semiconductor material, or a combination thereof. The group IV semiconductor material may include, e.g., silicon (Si), germanium (Ge), or a combination thereof. The III-V group semiconductor material may include, e.g., gallium arsenide (GaAs), indium phosphide (InP), gallium phosphide (GaP), indium arsenide (InAs), indium antimony (InSb), indium gallium arsenide (InGaAs), or a combination thereof. The II-VI group semiconductor material may include, e.g., zinc telluride (ZnTe), cadmium sulfide (CdS), or a combination thereof.

In an implementation, the passive element chip 500 may include a second substrate 520 on the first substrate 510. The second substrate 520 may have a first surface 520A contacting the first substrate 510 and a second surface 520B opposite to the first surface 520A. In an implementation, the through electrode 514 of the first substrate 510 may be connected to the second substrate 520 through or at the first surface 520A of the second substrate 520. In an implementation, as shown in FIG. 2, the first substrate 510 may include a first substrate pad 518 on or at an upper surface of the first substrate 510, and the through electrode 514 may be connected to the first substrate pad 518.

The second substrate 520 may include a second substrate body 524 and a passive element 522 buried inside the second substrate body 524. The second substrate body 524 may include a semiconductor material, such as a group IV semiconductor material, a group III-V semiconductor material, a group II-VI semiconductor material, or a combination thereof. The group IV semiconductor material may include, e.g., silicon (Si), germanium (Ge), or a combination thereof. The III-V group semiconductor material may include, e.g., gallium arsenide (GaAs), indium phosphide (InP), gallium phosphide (GaP), indium arsenide (InAs), indium antimony (InSb), indium gallium arsenide (InGaAs), or a combination thereof. The II-VI group semiconductor material may include, e.g., zinc telluride (ZnTe), cadmium sulfide (CdS), or a combination thereof.

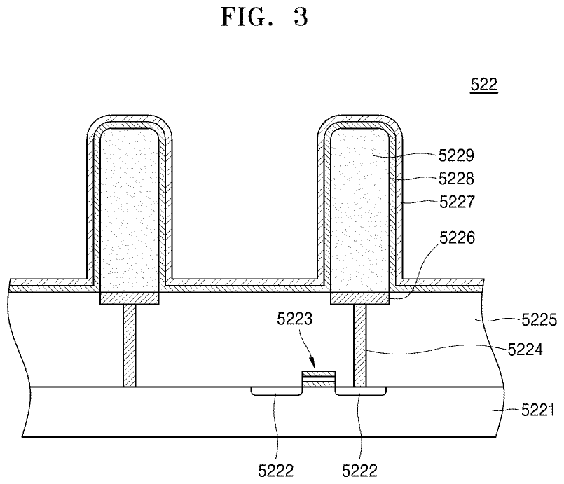

The passive element 522 may include a capacitor. In an implementation, a capacitor that the passive element 522 may include may include a multilayer ceramic capacitor (MLCC), a tantalum capacitor, a film capacitor, or an integrated stacked capacitor (ISC). Representatively, the passive element 522 may include an ISC, and the structure of the ISC is described below with reference to FIG. 3.

In an implementation, as illustrated in the drawings, the upper surface of the first substrate pad 518 may be on the same plane as the upper surface of the first substrate 510, the upper surface of the first substrate pad 518 may be lower than the upper surface of the first substrate and may be buried, or the upper surface of the first substrate pad 518 may be higher than the upper surface of the first substrate 510 to protrude. The second substrate 520 may include a second through substrate electrode 526 penetrating the second substrate body 524, and a first bonding pad 530 connected to the second through substrate electrode 526. In an implementation, the second substrate body 524 may include Si, and the second through-substrate electrode 526 may be a TSV.

In an implementation, an upper surface of the first bonding pad 530 may be on the same plane as an upper surface of the passive element chip 500. In an implementation, the upper surface of the first bonding pad 530 may be on the same plane as the second surface 520B of the second substrate 520. In an implementation, the upper surface of the first bonding pad 530 may be lower than the second surface 520B of the second substrate 520 and may be buried, or the upper surface of the first bonding pad 530 may be higher than the second surface 520B and may protrude.

In an implementation, the lower surface of the second bonding pad 610 may be on the same plane as the lower surface of the upper chip 600. In an implementation, the lower surface of the second bonding pad 610 may be on the same plane as a third surface 600A of the upper chip 600. In an implementation, the lower surface of the second bonding pad 610 may be higher than the third surface 600A of the upper chip 600 and may be buried, and the lower surface of the second bonding pad 610 may be lower than the third surface 600A and may protrude.

In an implementation, as illustrated in the drawings, the upper surface of the first bonding pad 530 may be on the same plane as the second surface 520B of the first substrate 510, or the upper surface of the first bonding pad 530 may be lower than the second surface 520B of the second substrate 520 and may be buried, or the upper surface of the first bonding pad 530 may be higher than the second surface 520B of the second substrate 520 and may protrude.

In an implementation, as shown in FIG. 2, the upper chip 600 to be described below may be on the second substrate 520 and in contact (e.g., direct contact) with the second surface 520B of the second substrate 520. The upper chip 600 may include an upper chip body 630 and an upper chip through electrode 640, and the upper chip through electrode 640 may extend through the upper chip body 630. The upper chip 600 may include a second bonding pad 610 on the third surface 600A of the upper chip, and the second bonding pad 610 may be connected to the upper chip through electrode 640. The second bonding pad 610 may contact and be connected to the first bonding pad 530 of the second substrate 520 with the third surface 600A of the upper chip 600 as a boundary. In an implementation, the first bonding pad 530, the second bonding pad 610, the through electrode 514, the second substrate through electrode 526, and the upper chip through electrode 640 may provide an electrical path through which electrical signals may move between the lower chip 310, the first substrate 510, the second substrate 520, and the upper chip 600.

In an implementation, the upper chip 600 may be mounted on the second surface 520B of the second substrate 520. The upper chip 600 may have a smaller size than the lower chip 310. In an implementation, a widest surface (e.g., maximum width of a surface) of the upper chip 600 may be narrower than the widest surface of the lower chip 310. The widest surface referred to herein may mean the surface parallel to the horizontal directions (X and Y directions). The upper chip 600 may have a third surface 600A contacting the second surface 520B of the second substrate 520 and a fourth surface 600B opposite to the third surface 600A. The third surface 600A of the upper chip 600 may be an active surface, and the fourth surface 600B may be an inactive surface. As used herein, the terms “first,” “second,” and the like are merely for identification and differentiation, and are not intended to imply or require sequential inclusion (e.g., a third element and a fourth element may be described without implying or requiring the presence of a first element or second element).

Second bonding pads 610 may be on the third surface 600A of the upper chip 600. The upper chip 600 may include an upper logic element 620 inside the upper chip body 630. The second bonding pads 610 of the upper chip 600 may be electrically connected to the upper logic element 620 through a wiring structure inside the upper chip body 630.

In an implementation, the upper chip 600 may be a non-memory chip. In an implementation, the upper logic element 620 may be a non-memory device. In an implementation, the upper chip 600 may be a logic chip including a deep learning model, a microprocessor, a graphics processor, a signal processor, a network processor, a chipset, an audio codec, a video codec, or an application processor.

In an implementation, the upper chip 600 may include a volatile memory chip or a non-volatile memory chip. In an implementation, the upper logic element 620 may be a volatile memory device or a non-volatile memory device. The volatile memory chip may include, e.g., dynamic random access memory (DRAM), static RAM (SRAM), thyristor RAM (TRAM), zero capacitor RAM (ZRAM), or twin transistor RAM (TTRAM). In an implementation, the non-volatile memory chips may include, e.g., a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, or an insulation resistance change memory.

A third surface of the upper chip 600 on which the second bonding pads 610 are formed may face the second substrate 520 of the passive element chip 500. The second bonding pads 610 of the upper chip 600 may be electrically connected to the passive element chip 500 through the first bonding pads 530 of the second substrate 520. The second bonding pads 610 may be terminals for transmitting input/output data signals of the upper chip 600 or terminals for power or grounding of the upper chip 600.

In an implementation, one surface of the second substrate 520 of the passive element chip 500 may contact and bond with one surface of the upper chip 600. In an implementation, the second surface 520B of the second substrate 520 may contact the third surface 600A of the upper chip 600. In this case, the first bonding pad 530 on the second surface 520B of the second substrate 520 may be bonded to the second bonding pad 610 on the third surface 600A of the upper chip 600. The first bonding pad 530 and the second bonding pad 610 may include a conductive material such as metal. In an implementation, the first bonding pad 530 and the second bonding pad 610 may form hybrid bonding between metals. In an implementation, the first bonding pad 530 may have a continuous configuration with the second bonding pad 610, and a boundary between the first bonding pad 530 and the second bonding pad 610 may not be visually visible. In an implementation, the first bonding pad 530 may be made of the same material (e.g., copper (Cu)) as the second bonding pad 610, and there may be no interface between the first bonding pad 530 and the second bonding pad 610. In an implementation, the first bonding pad 530 and the second bonding pad 610 may be provided as one, e.g., monolithic or integrated, component. The passive element chip 500 and the upper chip 600 may be electrically connected to each other through the first bonding pad 530 and the second bonding pad 610.

In the semiconductor package 10 according to an embodiment, the passive element chip 500 including the passive element 522 such as a capacitor may be physically close to the upper chip 600 including the upper logic element 620. In an implementation, the passive element chip 500 may be physically close to the upper chip 600 including the upper logic element 620, and power loss due to resistance of wires in the upper chip 600 may be reduced.

The width of the first substrate 510 in the first horizontal direction (X direction) may be the same as the width of the second substrate 520 in the first horizontal direction (X direction) and the width of the upper chip 600 in the first horizontal direction (X direction). In an implementation, the side of the first substrate 510, the side of the second substrate 520, and the side of the upper chip 600 may be aligned. The first substrate 510, the second substrate 520, and the upper chip 600 may overlap the lower chip 310 in the vertical direction (Z direction). In an implementation, when viewed from a vertical perspective, e.g., in a plan view, the first substrate 510, the second substrate 520, and the upper chip 600 may be arranged so as not to deviate from the upper surface of the lower chip 310.

The molding layer 230 may be mounted on the package substrate 100 to cover the lower chip 310, the passive element chip 500, and the upper chip 600. In an implementation, the molding layer 230 may include an insulating polymer or an epoxy resin. In an implementation, the molding layer 230 may include an epoxy molding compound (EMC).

In an implementation, the lower surface of the molding layer 230 may be on the same plane as the upper surface of the package substrate 100. In an implementation, an upper surface of the molding layer 230 may be on the same plane as a lower surface of the upper redistribution structure 700. In an implementation, the upper surface of the first substrate 510 and the lower surface of the second substrate 520 of the passive chip 500 may be in contact with each other, and the molding layer 230 may not be between the first substrate 510 and the second substrate 520. In an implementation, the upper surface of the second substrate 520 of the passive element chip 500 may be in contact with the lower surface of the upper chip 600, and the molding layer 230 may not be between the second substrate 520 and the upper chip 600.

In an implementation, the vertical connection structure 200a may connect the package substrate 100 and the upper redistribution structure 700. In an implementation, the vertical connection structure 200a may include an intermediate pad 210 and a conductive post 220. The intermediate pad 210 may be on the upper surface of the package substrate 100 and may electrically connect the lower chip 310 or the conductive post 220 (on the package substrate 100) to the package substrate 100. The intermediate pad 210 may be connected to the conductive vias 110 of the package substrate 100. The intermediate pad 210 may extend the horizontal directions (X and Y directions) on the upper surface of the package substrate 100. The intermediate pad 210 may be made of a conductive material such as metal.

The conductive post 220 may vertically penetrate the molding layer 230 to electrically connect the intermediate pad 210 (on the package substrate 100) and the upper redistribution structure 700. In an implementation, the intermediate pad 210 may be connected to the upper redistribution via 710 of the upper redistribution structure 700. In an implementation, as shown in FIG. 1, the height of the conductive post 220 in the vertical direction (Z direction) may be greater than the sum of the respective heights of the lower chip 310, the first substrate 510, the second substrate 520, and the upper chip 600 in the vertical direction (Z direction).

In an implementation, the conductive post 220 may be outside (e.g., laterally adjacent to) the lower chip 310, the passive element chip 500, and the upper chip 600, and may be a post including a conductive material. In an implementation, the conductive post 220 may be on the package substrate 100 and may surround or be at the side of the lower chip 310.

In an implementation, the conductive post 220 may be electrically connected to the conductive vias 110 and the conductive patterns 120 of the package substrate 100, the upper redistribution via 710 of the upper redistribution structure 700, and the upper redistribution conductive layer 720. In an implementation, the conductive posts 220 may provide a travel path for data signals.

The upper redistribution structure 700 may be on a fourth surface 600B of the upper chip 600. In an implementation, the upper redistribution structure 700 may be in contact with the upper surface of the molding layer 230. The upper redistribution structure 700 may include an upper redistribution via 710, an upper redistribution conductive layer 720, and an upper redistribution insulating layer 730.

The upper redistribution insulating layer 730 may be on the fourth surface 600B of the upper chip 600 and may include an insulating material. In an implementation, a material of the upper redistribution insulating layer 730 may include oxide or nitride.

The upper redistribution conductive layer 720 may extend in the horizontal directions (X direction and Y direction) inside the upper redistribution insulating layer 730. The upper redistribution conductive layer 720 may be electrically connected to the conductive vias 110, the conductive patterns 120, the lower chip 310, the passive element chip 500, the upper chip 600, and the upper redistribution via 710 of the package substrate 100. In an implementation, the upper redistribution conductive layer 720 may provide a movement path of data signals toward the lower chip 310, the passive element chip 500, and the upper chip 600.

The upper redistribution via 710 may extend in a vertical direction inside the upper redistribution insulating layer 730. In an implementation, the upper redistribution via 710 may be between lower and upper surfaces of the plurality of upper redistribution conductive layers 720 to connect electrical signals between the plurality of upper redistribution conductive layers 720.

The upper redistribution via 710 and the upper redistribution conductive layer 720 may include a conductive material that may include, e.g., copper (Cu), gold (Au), silver (Ag), nickel (Ni), tungsten (W), aluminum (Al), or combinations thereof. In an implementation, the upper redistribution via 710 and the upper redistribution conductive layer 720 may further include a barrier material to help prevent the conductive material from diffusing out of the upper redistribution via 710 and the upper redistribution conductive layer 720. The barrier material may include, e.g., titanium (Ti), tantalum (Ta), titanium nitride (TiN), tantalum nitride (TaN), or a combination thereof.

FIG. 3 is an enlarged cross-sectional view of the passive element shown in FIG. 2. The passive element shown in FIG. 3 is an integrated stacked capacitor (ISC).

The passive element 522 according to an embodiment may include a semiconductor substrate 5221, source and drain regions 5222 at predetermined intervals in the semiconductor substrate 5221, a gate structure 5223 electrically connected to the source and drain regions 5222, an interlayer dielectric (ILD) 5225 for performing interlayer insulation, a lower electrode 5529 sequentially on the ILD 5225, a dielectric layer 5528 having a high dielectric constant, and an upper electrode 5227. In an implementation, a conductive plug 5524 may penetrate the ILD 5525 to electrically connect the lower electrode 5529 and the source and drain regions 5222, and a TiN layer 5526 may be on the conductive plug 5524 as a diffusion barrier.

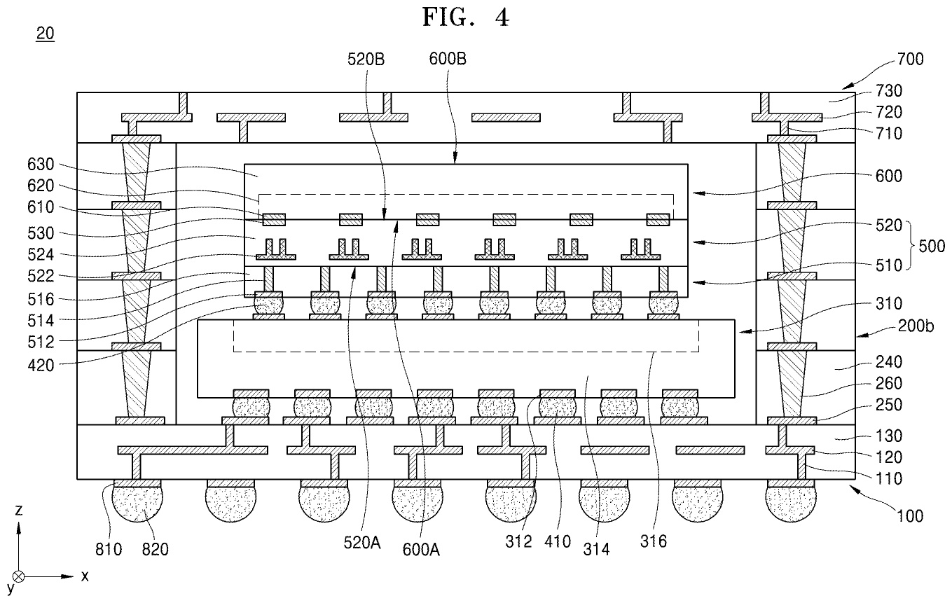

FIG. 4 is a cross-sectional view of a semiconductor package 20 according to another embodiment. When compared to the semiconductor package 10 shown in FIG. 1, the semiconductor package 20 shown in FIG. 4 is almost the same except that the structure of the vertical connection structure 200 is different. In an implementation, the semiconductor package 10 illustrated in FIG. 1 is a wafer level package (WLP), whereas the semiconductor package 20 illustrated in FIG. 4 may be a panel level package (PLP). Hereinafter, descriptions of components already described with reference to FIG. 1 may be omitted.

A vertical connection structure 200b may include a plurality of base layers 240, a plurality of substrate line patterns 250, and a plurality of substrate via patterns 260 stacked in the vertical direction (Z direction) on a package substrate 100. The plurality of base layers 240 may be stacked in the vertical direction (Z direction) on the package substrate 100 to surround or be at a side of a lower chip 310, a first substrate 510 and a second substrate 520 of a passive element chip 500, and the upper chip 600.

The plurality of substrate line patterns 250 may be on upper or lower surfaces of the plurality of base layers 240. In an implementation, the plurality of substrate line patterns 250 may extend parallel to a plurality of horizontal directions (X and Y directions).

The plurality of substrate via patterns 260 may vertically pass through the plurality of base layers 240 and connect the plurality of substrate line patterns 250 to each other. The plurality of substrate via patterns 260 may electrically connect the plurality of substrate line patterns 250 to each other. In an implementation, the plurality of substrate line patterns 250 and the plurality of substrate via patterns 260 may electrically connect the package substrate 100 to the upper redistribution structure 700.

The plurality of substrate line patterns 250 and the plurality of substrate via patterns 260 may include a conductive material that may include, e.g., copper (Cu), gold (Au), silver (Ag), nickel (Ni), tungsten (W), aluminum (Al), or a combination thereof. In an implementation, the plurality of substrate line patterns 250 and the plurality of substrate via patterns 260 may further include a barrier material to help prevent the conductive material from diffusing out of the plurality of substrate line patterns 250 and the plurality of substrate via patterns 260. The barrier material may include, e.g., titanium (Ti), tantalum (Ta), titanium nitride (TiN), tantalum nitride (TaN), or a combination thereof.

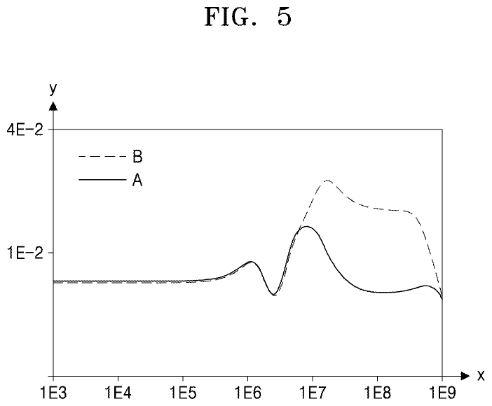

FIG. 5 is a graph illustrating effects of a semiconductor package according to an embodiment. In the graph of FIG. 5, the X axis represents the frequency of the current flowing in the wiring provided in the lower chip 310 (hereinafter referred to as FIG. 1), and the Y axis represents the impedance of the wiring.

In the graph shown in FIG. 5, line A represents an impedance of a wiring provided in the lower chip 310 depending on the frequency of the current of the semiconductor package 10 according to an embodiment, and line B represents an impedance of wiring provided in a chip depending on the frequency of current in a comparative semiconductor package. Referring to line A in the case of the semiconductor package 10 according to an embodiment, it may be seen that the impedance of the wiring in the lower chip 310 was greatly reduced when a high-frequency current flowed. In detail, when the frequency was 1E8 rad/s, an impedance of the wiring provided in the chip of the comparative semiconductor package was about 20.8 mΩ, whereas an impedance of wiring in the lower chip 310 of the semiconductor package according to an embodiment may be about 13.2 mΩ. Therefore, the semiconductor package 10 according to an embodiment may help reduce power loss due to resistance as the impedance provided in the chip is reduced in a high frequency band.

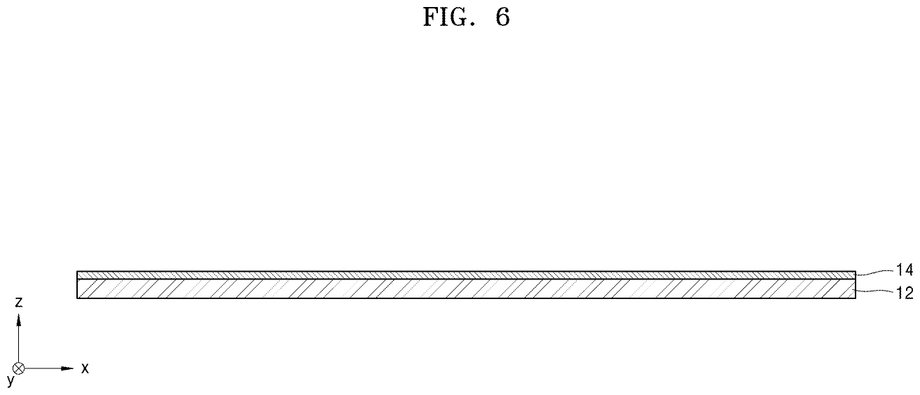

FIGS. 6 to 12 are cross-sectional views of stages in a process of manufacturing the semiconductor package 10 of FIG. 1

Referring to FIG. 6, a method of manufacturing the semiconductor package 10 according to this embodiment may first include providing a carrier substrate 12 to which a release film 14 may be attached.

The carrier substrate 12 may be made of a suitable material that is stable to a baking process, an etching process, and the like. When the carrier substrate 12 is to be separated and removed later by laser ablation, the carrier substrate 12 may be a light-transmitting substrate. In an implementation, when the carrier substrate 12 is to be separated and removed by heating later, the carrier substrate 12 may be a heat-resistant substrate.

In an implementation, the carrier substrate 12 may be a glass substrate. In an implementation, the carrier substrate 12 may be made of a heat-resistant organic polymer material, e.g., polyimide (PI), polyetheretherketone (PEEK), polyethersulfone (PES), or polyphenylene sulfide (PPS).

The release film 14 may be, e.g., a laser-responsive layer capable of being separated from the carrier substrate 12 by being vaporized in response to laser irradiation later. The release film 14 may include a carbon material layer. In an implementation, the release film 14 may include an amorphous carbon layer (ACL).

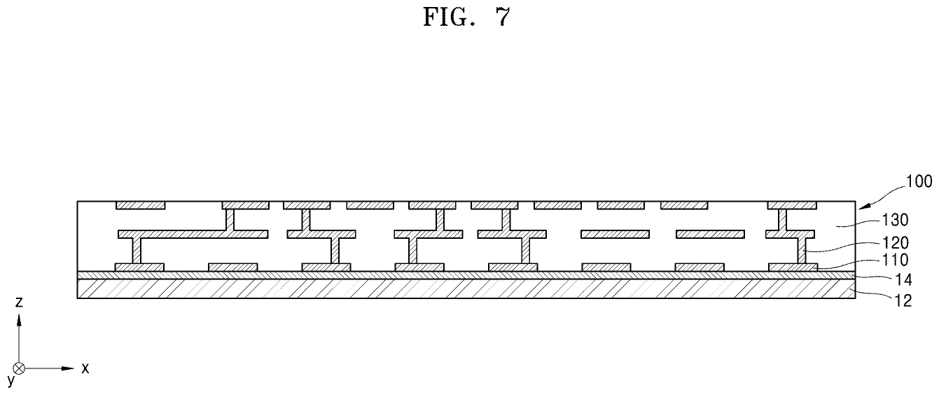

Referring to FIG. 7, the method of manufacturing the semiconductor package 10 according to an embodiment may include forming the package substrate 100 on the release film 14. As described above, a package substrate 100 may include conductive vias 110, conductive patterns 120, and a substrate base 130.

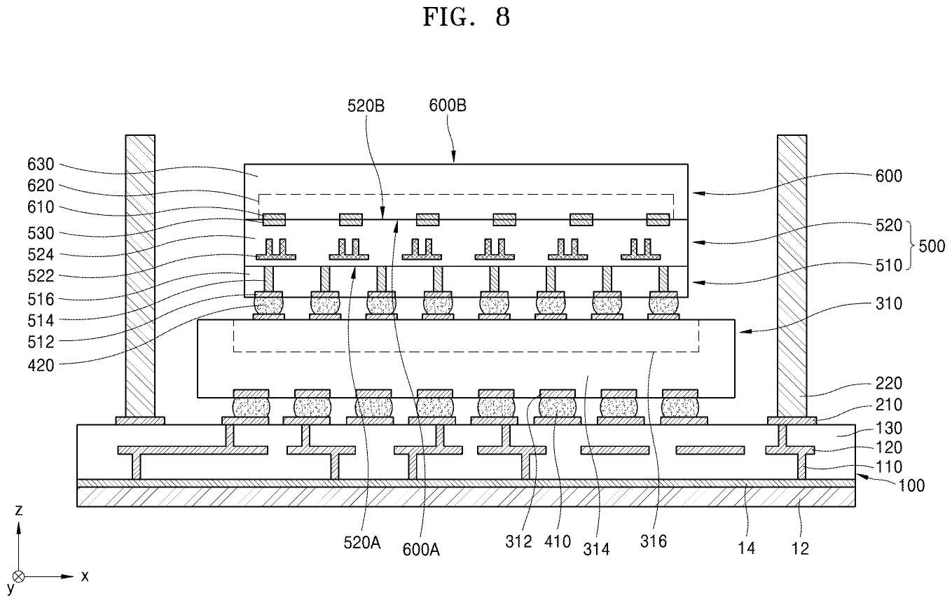

Referring to FIG. 8, conductive posts 220 may be formed on the package substrate 100. The conductive post 220 may be formed on an upper surface of an intermediate pad 210. In an implementation, photo-resist (PR) may be applied on the package substrate 100 to form the conductive posts 220. PR may be applied through a spin coating method using, e.g., a spin coater. After applying the PR, an exposure process may be performed. The exposure process may be performed using a mask including a specific pattern. In an implementation, a predetermined portion of the PR may be irradiated with light by transmitting light through a transparent portion of the transmissive mask. The chemical properties of the PR portion irradiated with light may be changed. After the specific portion is exposed to light, the exposed portion may be removed through a developing process. The conductive post 220 may be formed by filling a conductive material in a portion where the exposed portion is removed.

In an implementation, a plurality of chips 310, 500, and 600 may be disposed on the package substrate 100. A lower chip 310 may be mounted on the package substrate 100 in a flip-chip structure using a first chip connection terminal 410. In an implementation, an underfill may be filled between the package substrate 100 and the lower chip 310 and between the first chip connection terminals 410.

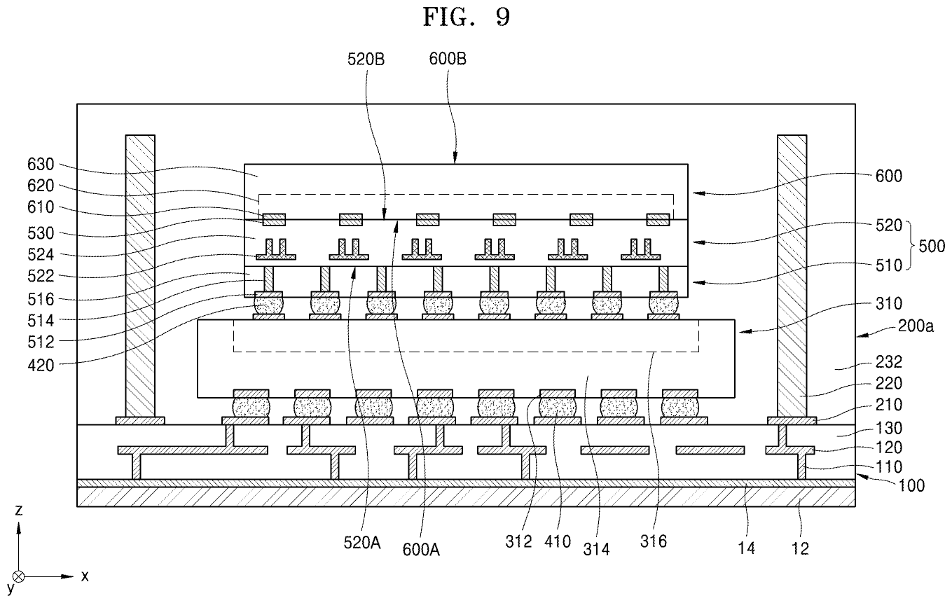

Referring to FIG. 9, after mounting the plurality of chips 310, 500, and 600 on the package substrate 100, a sealant 232 covering the plurality of chips and the conductive posts 220 may be formed on the package substrate 100. The sealant 232 may cover the upper and side surfaces of the upper chip 600 and the upper and side surfaces of the conductive posts 220. The material of the sealant 232 may be as described for the molding layer 230 of FIG. 1.

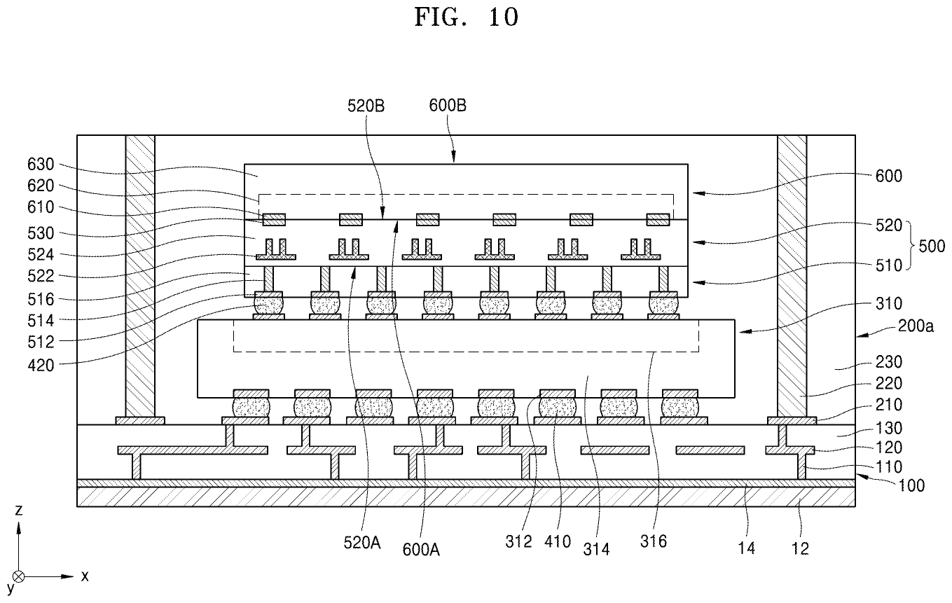

Referring to FIG. 10, a molding layer 230 may be formed through a planarization process of removing an upper portion of the sealant 232. The planarization process may be performed by, e.g., chemical mechanical polishing. Through the planarization process of the sealant 232, an upper surface of the conductive post 220 may be exposed from the sealant 232. In an implementation, in the planarization process of the sealant 232, the conductive post 220 may act as an etch stop layer. After the planarization process of the sealant 232, when the upper surface of the conductive post 220 forms substantially the same plane as the upper surface of the sealant 232, the molding layer 230 may be completed.

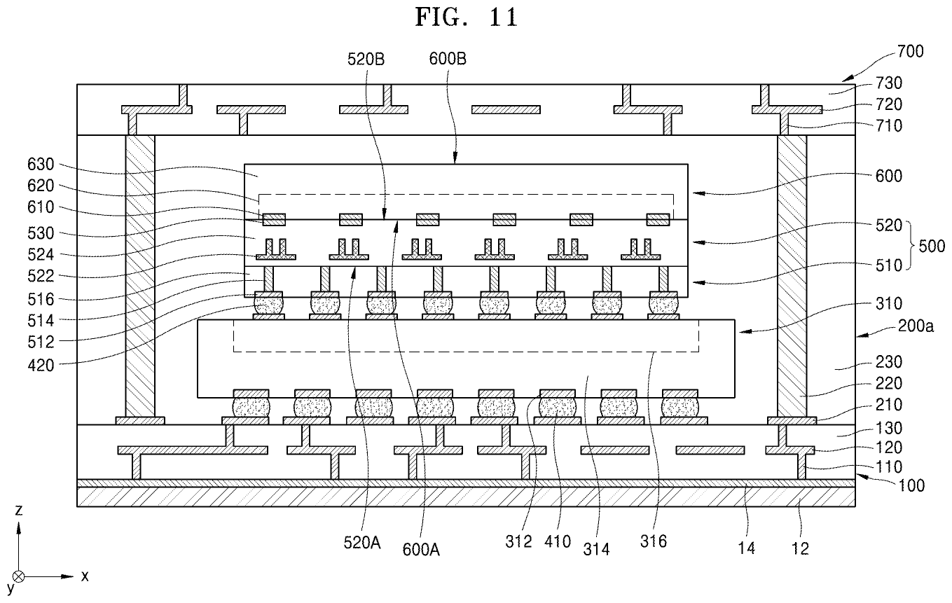

Referring to FIG. 11, an upper redistribution structure 700 may be formed on the conductive posts 220 and the molding layer 230. The upper redistribution structure 700 may include an upper redistribution via 710, an upper redistribution conductive layer 720, and an upper redistribution insulating layer 730. The upper redistribution via 710 of the upper redistribution structure 700 may be connected to the conductive post 220. In an implementation, the upper redistribution structure 700 may be as described in FIG. 1.

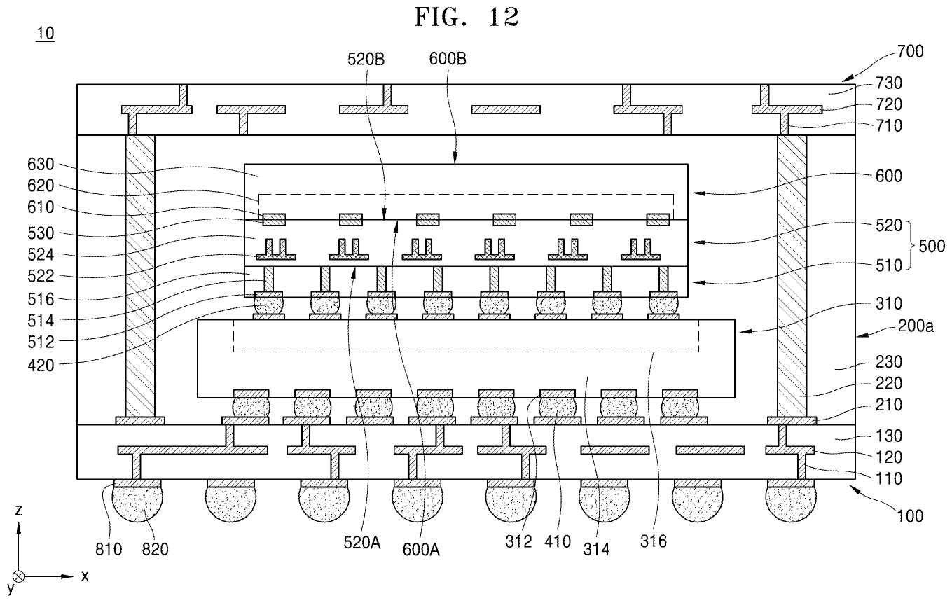

Referring to FIG. 12, thereafter, the carrier substrate 12 and the release film 14 may be separated from the package substrate 100, and external connection pads 810 may be formed on a lower surface of the package substrate 100. The external connection pads 810 may be connected to the conductive vias 110 of the package substrate 100. Then, external connection terminals 820 may be disposed on the lower surface of the external connection pads 810. The semiconductor package 10 of FIG. 1 may be completed through the arrangement of the external connection terminals 820.

By way of summation and review, the importance of the structure of the semiconductor package may be increasing with respect to responding to the size/performance of the semiconductor package and stably supplying power to the semiconductor package.

One or more embodiments may provide a semiconductor package in which two dies are directly stacked by wafer-to-wafer bonding.

One or more embodiments may provide a semiconductor package capable of increasing power supply efficiency by reducing impedance by arranging a passive element chip including a capacitor physically close to a semiconductor chip including a logic element.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a package substrate;
an upper chip on the package substrate;
a passive element chip between the upper chip and the package substrate; and
a lower chip between the passive element chip and the package substrate,
wherein:
the passive element chip includes:
a through electrode connected to the lower chip; and
a plurality of passive elements on the through electrode, and
an upper surface of the passive element chip is in contact with a lower surface of the upper chip.

2. The semiconductor package as claimed in claim 1, wherein a widest surface of the lower chip is wider than a widest surface of the passive element chip.

3. The semiconductor package as claimed in claim 2, further comprising a chip connection terminal on a lower surface of the passive element chip,
wherein the chip connection terminal connects the through electrode to the lower chip.

4. The semiconductor package as claimed in claim 1, wherein the passive element includes an integrated stacked capacitor.

5. The semiconductor package as claimed in claim 1, wherein:
a width of the passive element chip in a horizontal direction is the same as a width of the upper chip in the horizontal direction, and
a side surface of the passive element chip is aligned with a side surface of the upper chip.

6. The semiconductor package as claimed in claim 1, wherein:
the passive element chip includes a first bonding pad at an upper surface thereof,
the upper chip includes a second bonding pad at a lower surface thereof, and
an upper surface of the first bonding pad is bonded to a lower surface of the second bonding pad.

7. The semiconductor package as claimed in claim 6, wherein the first bonding pad and the second bonding pad are integrally made of the same material.

8. The semiconductor package as claimed in claim 6, wherein:
the upper surface of the first bonding pad is on the same plane as the upper surface of the passive element chip, and
the lower surface of the second bonding pad is on the same plane as the lower surface of the upper chip.

9. The semiconductor package as claimed in claim 6, wherein a width of the first bonding pad in a horizontal direction is equal to a width of the second bonding pad in the horizontal direction.

10. The semiconductor package as claimed in claim 1, wherein the upper chip includes a logic element.

11. A semiconductor package, comprising:
a package substrate;
a first chip connection terminal on the package substrate;
a lower chip on the package substrate and connected to the package substrate through the first chip connection terminal;
a second chip connection terminal on the lower chip, the second chip connection terminal being smaller than the first chip connection terminal;
a passive element chip on the lower chip and connected to the lower chip through the second chip connection terminal; and
an upper chip on the passive element chip,
wherein:
the passive element chip includes:
a first substrate including a through electrode therein connected to the second chip connection terminal; and
a second substrate on the first substrate, providing a first surface in contact with the first substrate and a second surface opposite to the first surface, and connected to the through electrode,
the upper chip includes:
a third surface in contact with the second surface of the second substrate,
a fourth surface opposite to the third surface, and
a logic element therein, and
the second substrate includes a passive element therein.

12. The semiconductor package as claimed in claim 11, wherein the first substrate, the second substrate, and the upper chip vertically overlap the lower chip.

13. The semiconductor package as claimed in claim 11, wherein:
a width of the first substrate in a horizontal direction is the same as a width of the second substrate in the horizontal direction and a width of the upper chip in the horizontal direction, and
a side surface of the first substrate, a side surface of the second substrate, and a side surface of the upper chip are aligned with each other.

14. The semiconductor package as claimed in claim 11, wherein the passive element includes an integrated stacked capacitor.

15. The semiconductor package as claimed in claim 11, further comprising a conductive post on the package substrate and adjacent to the lower chip, the first substrate, the second substrate, and the upper chip,
wherein a vertical height of the conductive post is greater than a sum of respective vertical heights of the lower chip, the first substrate, the second substrate, and the upper chip.

16. The semiconductor package as claimed in claim 11, further comprising a molding layer on the lower chip, the first substrate, the second substrate, and the upper chip,
wherein the molding layer is not in a space between the first substrate and the second substrate and is not in a space between the second substrate and the upper chip.

17. The semiconductor package as claimed in claim 11, wherein:
the second substrate includes a first bonding pad at the second surface thereof,
the upper chip includes a second bonding pad at the third surface thereof, and
the first bonding pad is bonded to the second bonding pad.

18. The semiconductor package as claimed in claim 11, further comprising
a plurality of base layers vertically stacked on the package substrate and surrounding the lower chip, the first substrate, the second substrate, and the upper chip;
a plurality of substrate line patterns at an upper surface or a lower surface of the plurality of base layers; and
a plurality of substrate via patterns vertically passing through the plurality of base layers and connecting the plurality of substrate line patterns to each other.

19. A semiconductor package, comprising:
a package substrate;
a first chip connection terminal on the package substrate;
a lower chip on the package substrate and connected to the package substrate through the first chip connection terminal;
a conductive post on the package substrate, the conductive post being adjacent to the lower chip;
a second chip connection terminal on the lower chip, the second chip connection terminal being smaller than the first chip connection terminal;
a passive element chip on the lower chip, the passive element chip including a through electrode connected to the second chip connection terminal and a plurality of passive elements on the through electrode;
an upper chip in contact with a top surface of the passive element chip, the upper chip including a logic element;
a sealing layer sealing the lower chip, the passive element chip, and the upper chip and having an upper surface on the same plane as an upper surface of the conductive post; and
an upper redistribution structure on the conductive posts and the sealing layer and electrically connected to the conductive posts.

20. The semiconductor package as claimed in claim 19, wherein:
the passive element chip includes:
a first substrate including the through electrode therein; and
a second substrate on the first substrate and connected to the through electrode,
the second substrate includes a first bonding pad at an upper surface thereof,
the upper chip includes a second bonding pad at a lower surface thereof, and
the first bonding pad is bonded to the second bonding pad.
